(19) United States
(12) Patent Application Publication
(10) Pub. No.: US 2005/0080981 A1
(43) Pub. Date: Apr. 14, 2005

(54) Structure and method for managing workshares in a parallel region

(75) Inventors: Roch G. Archambault, North York (CA); Raul E. Silvera, Woodbridge (CA); Guansong Zhang, Toronto (CA)

Correspondence Address: Mark S. Walker;International Business Machines, Intellectual Property Law, 11400 Burnet Road, Austin, TX, 78758, US

(73) Assignee: INTERNATIONAL BUSINESS MACHINES CORPORATION, ARMONK, NY (US)

(21) Appl. No.: 10/845,553

(22) Filed: May 13, 2004

(30) Foreign Application Priority Data
Sep. 26, 2003 (CA) 2442803

(51) Int. Cl. G11C 5/00

(52) U.S. Cl. 711/1

(57) ABSTRACT

A data processing system is adapted to execute at least one workshare construct in a parallel region. The data processing system uses at least one thread for executing a corresponding subsection of the workshare construct and provides control blocks for managing corresponding workshare constructs in the parallel region. A method of managing the control blocks comprises: adding an array of control blocks to a control block queue; assigning control blocks in the initialized array to corresponding workshare constructs in the parallel region until a barrier is reached; and waiting at the barrier for all threads in the parallel region to complete their corresponding subsections and then resetting the control block to the beginning of the control block queue. Also provided are a computer program product and a data processing system for implementing the method.

The present invention relates to data processing systems in general, and more specifically to a structure and method for managing parallel threads for workshares in a parallel region.

### BACKGROUND OF THE INVENTION

OpenMP is the emerging industry standard for parallel programming on shared memory and distributed shared memory multiprocessors. Defined in OpenMP Specification FORTRAN version 2.0, 2000, http://www.openmp.org., and OpenMP Specification C/C++ version 2.0, 2002, http://www.openmp.org, by a group of major computer hardware and software vendors, OpenMP is a portable, scalable model that provides shared-memory parallel programmers with a simple and flexible interface for developing parallel applications for platforms ranging from desktops to supercomputers.

The OpenMP standard defines two major constructs to describe parallelism in a program. A parallel region is defined as a section of code to be executed in parallel by a team of threads. A workshare construct is a language construct that divides a task, or section of code, into multiple independent subtasks which can be run concurrently. When a parallel region contains a workshare construct, the subtasks are distributed among the threads in the team. It is possible, and often likely, that a parallel region will include a plurality workshare constructs that are accessed sequentially. Thus it can be seen that through parallel regions, multiple threads perform worksharing in an OpenMP program.

Referring to FIG. 1, an example of a parallel region is illustrated generally by numeral 100. In this example, a master thread 102 initiates the parallel region 100, which is executed by eight threads 104. Once the master thread 102 has initiated the parallel region 100, it can participate in the workshare constructs. The parallel region 100 further includes a plurality of workshare constructs 106. Once all of the workshare constructs 106 have been completed, the master thread 102 continues to run.

OpenMP allows a user to specify that after each thread finishes executing its share of the subtasks in a workshare construct, it can begin executing any subsequent tasks in the parallel region without having to wait for all threads in the team to complete their respective tasks. In this case, no synchronization is needed at the end of the workshare construct. This case is referred to as a NOWAIT workshare construct, or a workshare construct having a NOWAIT clause.

Since there can be multiple NOWAIT workshare constructs in sequence in a parallel region, under certain situations multiple workshare constructs can be active at the same time. For example, assume three threads are available for three NOWAIT workshare constructs. A first thread requires more time to complete its subtask in the first NOWAIT workshare construct than the second and third threads. As a result, the second and third threads continue forward and execute subtasks of the second NOWAIT workshare construct. Further, the third thread completes its subtask in the second NOWAIT workshare construct while the second thread is working in the second NOWAIT construct and the first thread is working in the first NOWAIT construct. As a result, the third thread continues forward and executes a subtask of the third NOWAIT workshare construct. In this example, all of the NOWAIT constructs are said to be active and their runtime information needs to preserved until all threads have finished their execution.

A simple solution to this problem is create a control block for each workshare for storing the necessary information. However, the number of workshare constructs that may be simultaneously active in a parallel region is generally unknown at compile time and, further, it may vary according to user input. One of the present solutions to the problem assigns a statically sized array to contain the control blocks. However, this implementation either aborts execution on overflow or introduces artificial delays to limit the number of active workshare constructs. Either of these solutions may severely affect the performance of some workloads or prevent them from executing successfully. If the entries in the array are reused to mitigate the occurrence of this limitation, costly synchronization needs to be invoked at the end of each NOWAIT workshare construct to ensure that the same entry is not used for two simultaneous active workshare constructs. Finally, the initialization of this structure needs to be performed at creation of the parallel region, introducing a fixed overhead to be paid on entry to every parallel region.

Using a dynamically sized structure also has drawbacks. For example, dynamic memory allocation frequently has a high overhead as it requires synchronization to access a shared storage pool. Furthermore, synchronization is necessary at the end of each workshare construct to release the allocated memory.

Accordingly, it is an object of the present invention to obviate and mitigate at least some of the above mentioned disadvantages.

### SUMMARY OF THE INVENTION

In accordance with an aspect of the present invention there is provided for a data processing system adapted to execute at least one workshare construct in a parallel region, the data processing system using at least one thread for executing a corresponding subsection of the workshare construct, the data processing system providing control blocks for managing corresponding workshare constructs in the parallel region, a method of managing the control blocks, the method comprising: adding an array of control blocks to a control block queue; assigning control blocks in the initialized array to corresponding workshare constructs in the parallel region until a barrier is reached; and waiting at the barrier for all threads in the parallel region to complete their corresponding subsections and then resetting the control block to the beginning of the control block queue.

In accordance with a further aspect of the present invention, there is provided a computer program product having a computer readable medium tangibly embodying computer executable code for directing a data processing system to execute at least one workshare construct in a parallel region using at least one thread for executing a corresponding subsection of the workshare construct, wherein control blocks are provided for managing corresponding workshare constructs in the parallel region, the computer program product comprising: code for initializing an array of control blocks and adding the array to a control block queue; and code for assigning control blocks in the initialized array to corresponding workshare constructs in the parallel region until a barrier is reached; code for waiting at the barrier for all threads in the parallel region to complete their subsections and resetting the control block to the beginning of the control block queue.

In accordance with yet a further aspect of the present invention, there is provided for for a data processing system adapted to execute at least one workshare construct in a parallel region, the data processing system using at least one thread for executing a corresponding subsection of the workshare construct, wherein control blocks are provided for managing corresponding workshare constructs in the parallel region, the data processing system comprising: means for initializing an array of control blocks and adding the array to a control block queue; means for assigning control blocks in the initialized array to corresponding workshare constructs in the parallel region until a barrier is reached; and means for waiting at the barrier for all threads in the parallel region to complete their subsections and resetting the control block to the beginning of the control block queue.

A better understanding of these and other embodiments of the present invention can be obtained with reference to the following drawings and description of the preferred embodiments.

### BRIEF DESCRIPTION OF THE DRAWINGS

An embodiment of the present invention will now be described by way of example only with reference to the following drawings in which:

FIG. 1 is block diagram illustrating a parallel region;

FIGS. 2a-d are block diagrams illustrating different possible workshare structures;

FIG. 3 is a Fortran pseudocode example of four DO constructs in a parallel region;

FIG. 4 is flow chart illustration the operation of an embodiment of the invention; and

FIGS. 5a-c are C pseudocode examples illustrating how the flow chart shown in FIG. 4 is implemented.

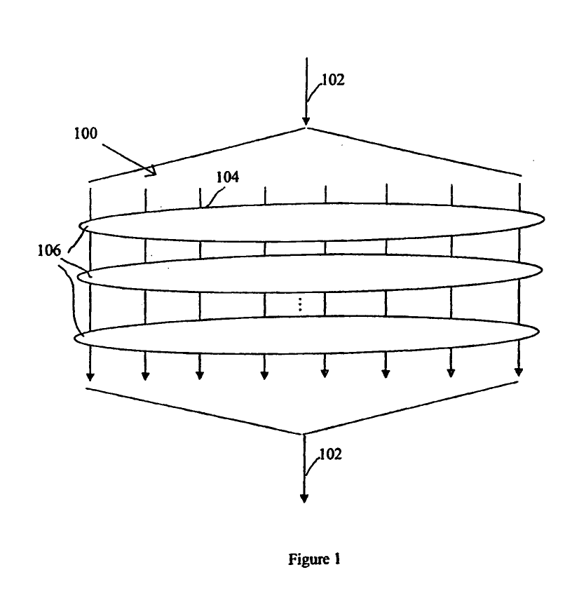

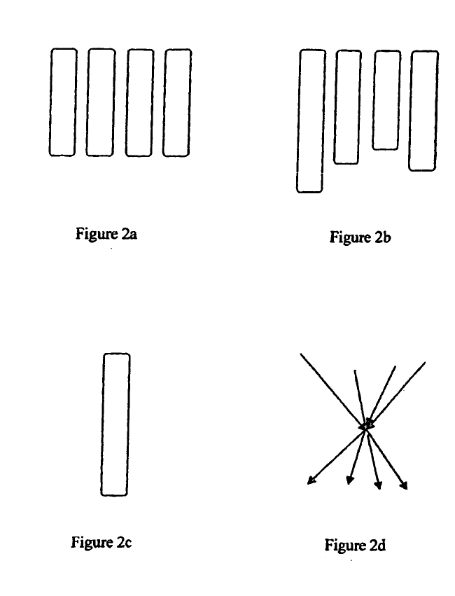

Similar references are used in different figures to denote similar components.

### DETAILED DESCRIPTION OF THE PREFERRED EMBODIMENT

The following detailed description of the embodiments of the present invention does not limit the implementation of the invention to any particular computer programming language. The present invention may be implemented in any computer programming language provided that the Operating System (OS) provides the facilities that may support the requirements of the present invention. A preferred embodiment is implemented in the C or C++ computer programming language (or other computer programming languages in conjunction with C/C++). Any limitations presented would be a result of a particular type of operating system or computer programming language and would not be a limitation of the present invention.

The most common forms of workshare constructs are worksharing DO and SECTIONS, illustrated in FIGS. 2(a) and (b) respectively. The primary difference between a DO construct and a SECTIONS construct is the type of code executed by the individual threads. In a SECTIONS construct the code segments executed by individual threads may be entirely different. In a DO construct the code segments executed by different threads are likely different iterations of the same code.

The DO construct illustrated in FIG. 2a assumes a worksharing DO having 100 iterations and executed by four threads. The iterations of the DO loop are shared among the threads such that each thread is responsible for 25 iterations. The SECTIONS construct is illustrated in FIG. 2b. A section of code is divided, in a manner known in the art, by a compiler into four subsections, one for each available thread. However, for both the DO construct and the SECTIONS construct, it is not known which of the threads will require the most time to complete its assigned portion of the code. Both the DO and SECTIONS constructs may have a NOWAIT clause, which allows threads to continue to a subsequent construct before the other threads have completed their tasks.

In addition to the common workshare constructs introduced above, other OpenMP structures may also be considered as workshare constructs, as will be appreciated by one of ordinary skill in the art. Typical examples include SINGLE constructs and explicit barriers, as illustrated in FIGS. 2(c) and (d).

A SINGLE construct is semantically equivalent to a SECTIONS construct having only one subsection. For a SINGLE construct, the first thread encounter the code will execute the subsection. This is different from a MASTER construct, where the decision can be made simply by checking the thread ID. The explicit barrier is semantically equivalent to a SECTIONS construct with no subsections and no NOWAIT clause.

Without the use of the NOWAIT clause, workshare DO, SECTIONS and SINGLE constructs have an implicit barrier at the end of the construct, which is why the explicit barrier can be considered to be in the same category. The advantage of considering the constructs as workshares is for practical coding. From an implementation perspective, the common behaviours of theses constructs will lead to a common code base to deal with different situations, which will improve the overall code quality. Thus, hereafter the term workshare is used to refer any of the workshares described above, as well as other workshares comprising similar attributes.

While the specific implementation of workshare constructs in a parallel region may differ from one case to another, each workshare construct requires a corresponding control block for maintaining control of the threads within the construct. Typically, the control block comprises the following structures.

A structure is required to hold workshare specific information such as an initial value and a final value of the loop induction variable and its schedule type. This type of information is necessary for storing information regarding DO or SECTIONS constructs, for example. Since multiple workshare constructs can exist in the same parallel region, this structure needs a “per workshare” value. That is, for each workshare in the parallel region there is a corresponding structure.

Further, a structure is required to complete possible barrier synchronization. This structure is used to implement an explicit barrier or an implicit barrier as needed for each workshare. The details of this structure are beyond the scope of the present invention and can be found in John M. Mellor-Crummey's and Michael L. Scott's Algorithms for Scalable Synchronization on Shared-Memory Multiprocessors, ACM Trans. on Computer Systems, 9(1):21-65, February 1991.

Yet further, a structure is required to control access to the workshare control block. This structure typically comprises a lock for ensuring that only one thread modifies the information of the shared control block. For example, marking the workshare as started or a particular section of code as completed.

Thus, it is preferable that the control block for each workshare construct includes all of the structures described above. Further, a queue of workshare control blocks is generally required for each parallel region. Details of implementing such structures as part of the control block are known in the art and need not be described in detail. However, it is desirable that the creation and manipulation of the control blocks in a parallel region occupy as little overhead as possible.

Since it cannot be statically predicted how many workshare constructs may exist in a parallel regions and how many of the workshare constructs will be active concurrently, the workshare control blocks are allocated dynamically. A workshare control block queue is constructed when a parallel region is encountered, and is destructed when the parallel region ends.

In accordance with an embodiment of the present invention a predetermined number of workshare control blocks are allocated as an array of control blocks. Initially, an array of control blocks is added to the control block queue. The control blocks are in the queue are reused as often as possible. Another array of control blocks is added to the control block queue when it is impossible to reuse any of the existing control blocks in the control block queue.

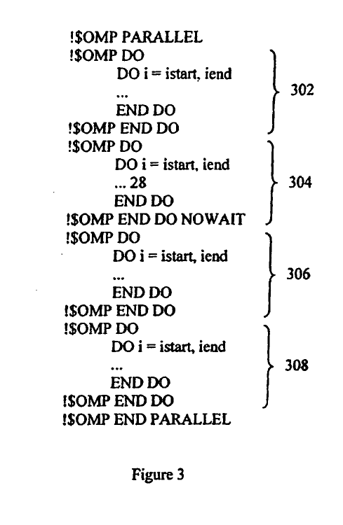

An example of the operation of the invention is illustrated in FIG. 3 by Fortran pseudocode for a sample parallel region. In the pseudocode, four workshare constructs 302, 304, 306, and 308 are defined in the parallel region. The first workshare construct 302 is a DO construct with an implicit barrier. Therefore, the instructions within the DO construct are divided amongst available threads for execution. As each thread completes its task, it waits for the remaining threads to complete their tasks. Once all threads have completed their tasks, the next workshare construct 304 is encountered.

The second workshare construct 304 is also a DO construct. However, the second workshare construct 304 has a NOWAIT clause and, thus, no implicit barrier. Therefore, the instructions within the DO construct are divided amongst available threads for execution. As each thread completes its task, it proceeds to the next workshare construct 306 without waiting for the remaining threads to complete their tasks. Thus, it is likely that two workshare constructs will be active at the same time. As a result, it can be seen that at least two control blocks may be necessary while completing the second workshare construct 304, since some threads may begin the third workshare construct 306.

The third workshare construct 306 is also a DO construct. Like the first workshare construct 302, the third workshare construct 306 also includes an implicit barrier. Therefore, the instructions within the DO construct are divided amongst available threads for execution. As each thread completes its task, it waits for the remaining threads to complete their tasks. Once all threads have completed their tasks, the next workshare construct 308 is encountered.

The fourth workshare construct 308 is also a DO construct including an implicit barrier. Therefore, the instructions within the DO construct are divided amongst available threads for execution. As each thread completes its task, it waits for the remaining threads to complete their tasks. Once all threads have completed their tasks, the parallel region is exited.

Thus it can be seen that if the control blocks for the workshare constructs are reused, the array of control blocks need only comprise two control blocks. That is, after the first workshare construct 302, the first control block can be reused. The execution of the second 304 and third 306 workshare constructs requires two control blocks, but after the third workshare construct 306, both control blocks can be reused. The fourth workshare construct 308, requires only one construct. The number of control blocks used is less than the prior art, in which case four control blocks would have been created, one for each workshare construct in the parallel region. Thus, the present invention provides an advantage over the prior art in that unnecessary memory allocation is reduced.

If the circumstances in the previous embodiment had been different such that the first three workshare constructs 302, 304 and 306 had a NOWAIT clause, four control blocks would have been required. Therefore, in accordance with the present embodiment of the invention, another array of control blocks is added to the control block pool, resulting a control block queue of four control blocks, as required.

Yet further, the manner in which the control block are initialized and utilized provide additional advantages over the prior. For example, the invention requires fewer locks than the prior for ensuring proper access to the control blocks. Also, the manner in which the blocks are reused reduces synchronization costs.

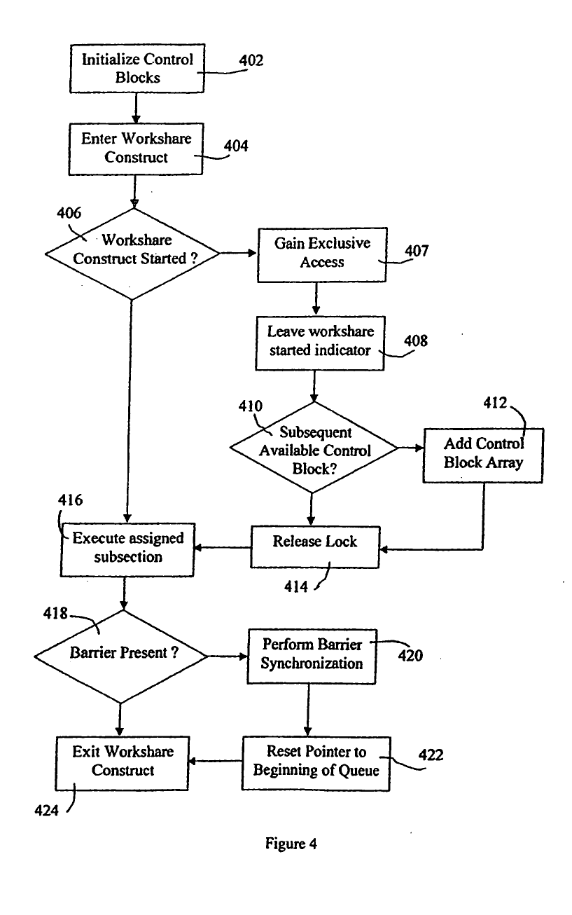

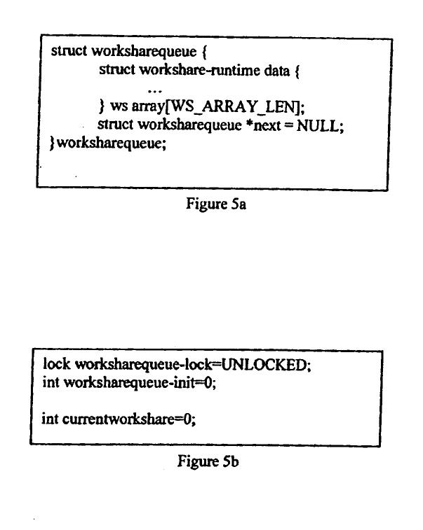

Referring to FIG. 4, a flow chart illustrating the execution of a workshare in a parallel region is shown. In step 402, a master thread initializes a first array of control blocks when entering the parallel region. Thus, a control block queue is ready for the first workshare construct. In step 404, a thread enters the workshare construct and, in step 406, determines if the workshare construct has been started. If the workshare construct has been started, the thread continues to step 416.

If the workshare construct has not yet been started, the thread proceeds to step 407 and gains exclusive access to the control block by locking it. While the control block is locked, the remaining threads cannot gain access and wait for the lock to be released before proceeding.

In step 408, the thread leaves an indicator that the workshare construct has been started. Further in step 410 it is determined if there is a subsequent available control block. If a subsequent control block is not available, the thread proceeds to step 412. In step 412, the thread instantiates an additional array of control blocks, adds it to the control block queue, and proceeds to step 414. If a subsequent control block is available, the thread proceeds directly to step 414.

In step 414, the thread releases the lock and continues to step 416 where it executes its assigned subsection of the instructions. At step 418, the thread has completed executing the instruction and determines if the workshare construct includes a barrier, either implicit or explicit. If the workshare construct includes a barrier, the thread continues to step 420, where a barrier synchronization is performed such that the thread waits for the remaining threads to complete the workshare construct. In step 422, once all threads have completed the workshare construct, a pointer indicating the next control block in the queue to be used is reset to the beginning of the queue. The thread then proceeds to step 424 and exits the worshare construct. If the workshare construct does not include a barrier, the thread continues from step 418 to step 424 and exits the worshare construct.

The next gains access to the control block and locks it, thus preventing other threads from accessing the control block simultaneously. This thread notes that the workshare construct has been started and, thus, realizes it is not the first thread to access the control block. As a result, the thread releases the lock and begins to execute its share of the instructions. This procedure continues until all threads have started executing their instructions in the workshare construct.

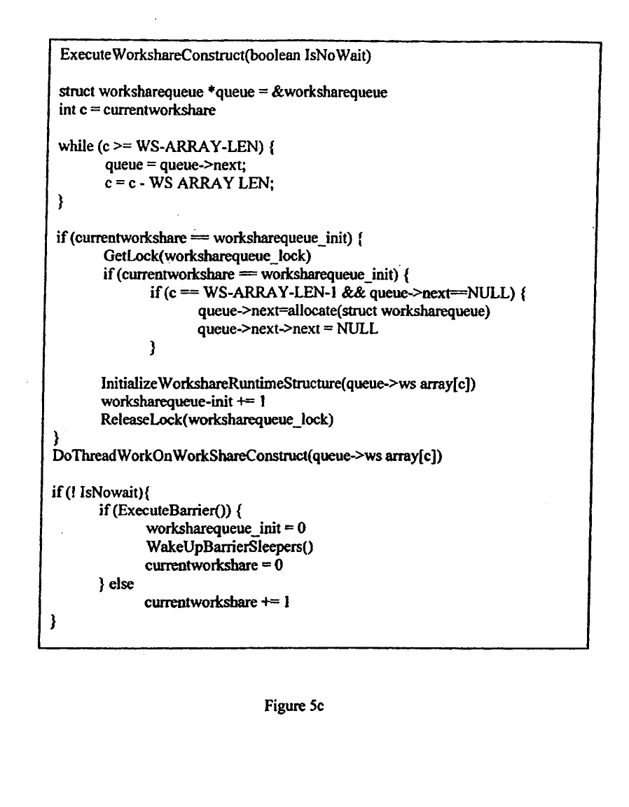

Referring to FIGS. 5a-c a pseudo-C code implementation of the flow chart illustrated in FIG. 4 is shown. Referring to FIG. 5a, an implementation of a control block array is illustrated. The sample code creates a worskshare queue ws_array comprising an array of control blocks. The content of the control blocks is defined by the worshare_runtime_data structure. The size of the array is defined by the variable WS_ARRAY_LEN, which is a predefined, user adjustable parameter.

Referring to FIG. 5b, several variables allocated at the beginning of each parallel region are shown. A lock variable, worksharequeue_lock, is initially set as unlocked. The lock variable is used for restricting access to the control block as required. An initialization variable, worksharequeue_init, is initially set to zero. The initialization variable is used for determining if a thread is the first thread to access a control block. Both the lock variable and the worksharequeue_init variable are considered to be global and, thus, all threads share access to them. A current workshare variable, currentworkshare, is initially set to zero. The current workshare variable is used for identifying which of the workshares, and accordingly, which of the control blocks, is being executed by the thread. Thus, the current workshare variable is a local variable and unique for each of the threads.

Referring to FIG. 5c, code for executing a workshare is illustrated. In the code shown a control block queue, queue, is defined as a pointer to a workshare structure. A local variable, c, is defined as the current workshare. A while loop is used for addressing the associated array of control blocks. Consider, for example, a case where there are eight workshares being executed concurrently and there is a control block array size of three. It is readily apparent that the control block for the eighth workshare is contained in the third array of control blocks in the control block pool. This is realized by the while loop as follows.

Since eight is greater than three, the while loop is entered. During the first execution of the while loop, the control block queue is directed to point to the second array of control blocks in the control block pool and the local variable, c, is reduced by three so that its new value is five. Since five is less than three, the while loop is repeated. During the second execution of the while loop, the control block queue is directed to point to the third array of control blocks in the control block pool and the local variable, c, is reduced by three so that its new value is two. Since two is less than three the while loop is exited.

The current workshare variable is compared to the initialization variable for determining if the thread is the first to access the control block for the current workshare construct. If the thread is the first to access the control block for the current workshare construct it attempts to get a lock on the on the control block. Once the thread receives the lock on the control block, it verifies that it is the first thread to access the control block. Once this fact is verified, the thread determines if the control block is the last control block in the current array of control blocks. The thread also determines if there is a subsequent array of control blocks that has already been allocated. If the control is the last control block in the queue and a subsequent array of control blocks has not yet been allocated, then the thread allocates another array of control blocks to the queue. The thread further initiates a control block for the current workshare structure, increments the count of the initialization variable, and releases the lock.

The remainder of the code is executed by all threads. The workshare construct assigns the desired work to the thread, which proceeds to execute its tasks. Once the work is completed, the thread determines if a NOWAIT condition exists for the current workshare. If a NOWAIT condition does not exist, a barrier is executed and the thread waits for the remaining threads to catch up. Once all the threads have caught up, the value for the current workshare variable is set to 0, since the control blocks that have been used thus far can be reused. If a NOWAIT condition does exist, the value of the current workshare is incremented and the thread proceeds to the next workshare construct.

Though the above embodiments are described primarily with reference to a method aspect of the invention, the invention may be embodied in alternate forms. In an alternative aspect, there is provided a computer program product having a computer-readable medium tangibly embodying computer executable instructions for directing a computer system to implement any method as previously described above. It will be appreciated that the computer program product may be a floppy disk, hard disk or other medium for long term storage of the computer executable instructions.

It will be appreciated that variations of some elements are possible to adapt the invention for specific conditions or functions. The concepts of the present invention can be further extended to a variety of other applications that are clearly within the scope of this invention. Having thus described the present invention with respect to a preferred embodiments as implemented, it will be apparent to those skilled in the art that many modifications and enhancements are possible to the present invention without departing from the basic concepts as described in the preferred embodiment of the present invention. Therefore, what is intended to be protected by way of letters patent should be limited only by the scope of the following claims.

1. For a data processing system adapted to execute at least one workshare construct in a parallel region, the data processing system using at least one thread for executing a corresponding subsection of the workshare construct, the data processing system providing control blocks for managing corresponding workshare constructs in the parallel region, a method of managing the control blocks, the method comprising:
adding an array of control blocks to a control block queue;
assigning control blocks in the initialized array to corresponding workshare constructs in the parallel region until a barrier is reached; and
waiting at the barrier for all threads in the parallel region to complete their corresponding subsections and then resetting the control block to the beginning of the control block queue.

2. The method of claim 1 further comprising initializing an additional array of control blocks and adding the additional array to the control block queue if the barrier is not reached before the end of the control block queue.

3. The method of claim 2, wherein the thread entering the workshare construct determines if it is the first thread to enter the workshare construct before executing its associated subsection.

4. The method of claim 3 wherein if the thread determines it is not the first thread to enter the workshare construct the thread proceeds to execute the subsection.

5. The method of claim 3, wherein if the thread determines it is the first thread to enter the workshare construct the thread sets an indicator in the corresponding control block that the workshare construct has been started and allocates the additional array of control blocks if necessary before executing the subsection.

6. The method of claim 5, wherein the thread allocates the additional array of control blocks if the control block corresponding to the workshare construct if the last control block in the array and the additional array has not previously been added to the control block queue.

7. The method of claim 5, wherein the thread attempts to obtain a lock upon determining that it is the first thread to enter the workshare construct.

8. The method of claim 7, wherein the lock is released before executing the subsection.

9. The method of claim 1, wherein the next available control block is reset to the beginning of the control block queue.

10. A computer program product having a computer readable medium tangibly embodying computer executable code for directing a data processing system to execute at least one workshare construct in a parallel region using at least one thread for executing a corresponding subsection of the workshare construct, wherein control blocks are provided for managing corresponding workshare constructs in the parallel region, the computer program product comprising:
code for initializing an array of control blocks and adding the array to a control block queue;
code for assigning control blocks in the initialized array to corresponding workshare constructs in the parallel region until a barrier is reached; and
code for waiting at the barrier for all threads in the parallel region to complete their subsections and resetting the control block to the beginning of the control block queue.

11. The computer program product of claim 10, further comprising code for initializing an additional array of control blocks and adding the additional array to the control block queue if the barrier is not reached before the end of the control block queue.

12. The computer program product of claim 11, further including code for determining if the thread is the first thread to enter the workshare construct before executing its associated subsection.

13. The computer program product of claim 12, further including code for executing the subsection.

14. The computer program product of claim 12, further comprising code for setting an indicator in the corresponding control block that the workshare construct has been started and allocating the additional array of control blocks if necessary before executing the subsection if the thread determines it is the first thread to enter the workshare construct.

15. The computer program product of claim 14, wherein the thread allocates the additional array of control blocks if the control block corresponding to the workshare construct if the last control block in the array and the additional array has not previously been added to the control block queue.

16. The computer program product of claim 14, further comprising code for obtaining a lock upon determining that it is the first thread to enter the workshare construct.

17. The computer program product of claim 16, further comprising code for releasing the lock before executing the subsection.

18. The computer program product of claim 10, wherein the next available control block is reset to the beginning of the control block queue.

19. For a data processing system adapted to execute at least one workshare construct in a parallel region, the data processing system using at least one thread for executing a corresponding subsection of the workshare construct, wherein control blocks are provided for managing corresponding workshare constructs in the parallel region, the data processing system comprising:
means for initializing an array of control blocks and adding the array to a control block queue;
means for assigning control blocks in the initialized array to corresponding workshare constructs in the parallel region until a barrier is reached; and
means for waiting at the barrier for all threads in the parallel region to complete their subsections and resetting the control block to the beginning of the control block queue.

20. The data processing system of claim 19, further including means for initializing an additional array of control blocks and adding the additional array to the control block queue if the barrier is not reached before the end of the control block queue.

21. The data processing system of claim 20, further including means for determining if the thread is the first thread to enter the workshare construct before executing its associated subsection.

22. The data processing system of claim 21, further including means for executing the subsection.

23. The data processing system of claim 21, further comprising means for setting an indicator in the corresponding control block that the workshare construct has been started and allocating the additional array of control blocks if necessary before executing the subsection if the thread determines it is the first thread to enter the workshare construct.

24. The data processing system of claim 23, wherein the thread allocates the additional array of control blocks if the control block corresponding to the workshare construct if the last control block in the array and the additional array has not previously been added to the control block queue.

25. The data processing system of claim 23, further comprising means for obtaining a lock upon determining that it is the first thread to enter the workshare construct.

26. The data processing system of claim 25, further comprising means for releasing the lock before executing the subsection.

27. The data processing system of claim 19, wherein the next available control block is reset to the beginning of the control block queue.
